(19) United States
(12) Patent Application Publication
(10) Pub. No.: US 2009/0308314 A1
(43) Pub. Date: Dec. 17, 2009

(54) VAPOR DEPOSITION DEVICE

(75) Inventor: SHIH-CHE CHIEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/346,812

(22) Filed: Dec. 30, 2008

(30) Foreign Application Priority Data
Jun. 11, 2008 (CN) 200810302100.4

(51) Int. Cl. B05C 11/00; C23C 16/54

(52) U.S. Cl. 118/712; 118/728

(57) ABSTRACT

A vapor deposition device includes a connecting member, a support member and an inspecting member. The connecting member has a connecting end. The support member has a bottom portion and a top portion positioned on the connecting end. Receiving holes are defined in the support component between the top portion and the bottom portion and configured to receive workpieces. Several pairs of through holes are defined in the support component adjacent to the bottom portion. Each pair of through holes is substantially coaxial with each other and positioned in a horizontal plane. The inspecting component includes a light emitting member and a light receiving member configured to be aligned with one pair of through holes.

### CROSS-REFERENCE STATEMENT

The present application is related to a pending U.S. patent application, titled “FILM COATING HOLDER AND FILM COATING DEVICE USING SAME”, filed on Jul. 28, 2008 with the application Ser. No. 12/181,157, assigned to the same assignee as the present application.

### BACKGROUND

1. Technical Field

The disclosure relates to a vapor deposition device.

2. Description of Related Art

Vapor deposition is a process of vaporizing film material supported on a crucible and depositing film material on workpieces.

A typical vapor deposition device includes a vacuum container, a support member, and an crucible. The support member is fixed on an inner surface of the vacuum container by threaded screws and positioned above the crucible. In coating, workpieces are received in the support member. Film materials are heated and vaporize by ion beams or electronic beams and then deposited on the workpieces. For coating a film with an identical thickness on each workpiece, the support member must be arranged in a horizontal position. However, it is difficult to adjust the support member in a horizontal position in assembling the typical vapor deposition.

Therefore, a new vapor deposition device is desired to overcome the above-described shortcoming.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a perspective view of one embodiment of a vapor deposition device.

FIG. 2 is an exploded view of the vapor deposition device of FIG. 1.

FIG. 3 is a cross-sectional view of the vapor deposition device of FIG. 1.

FIG. 4 is a partial cross-sectional view of another embodiment of a vapor deposition device.

### DETAILED DESCRIPTION OF THE EMBODIMENTS

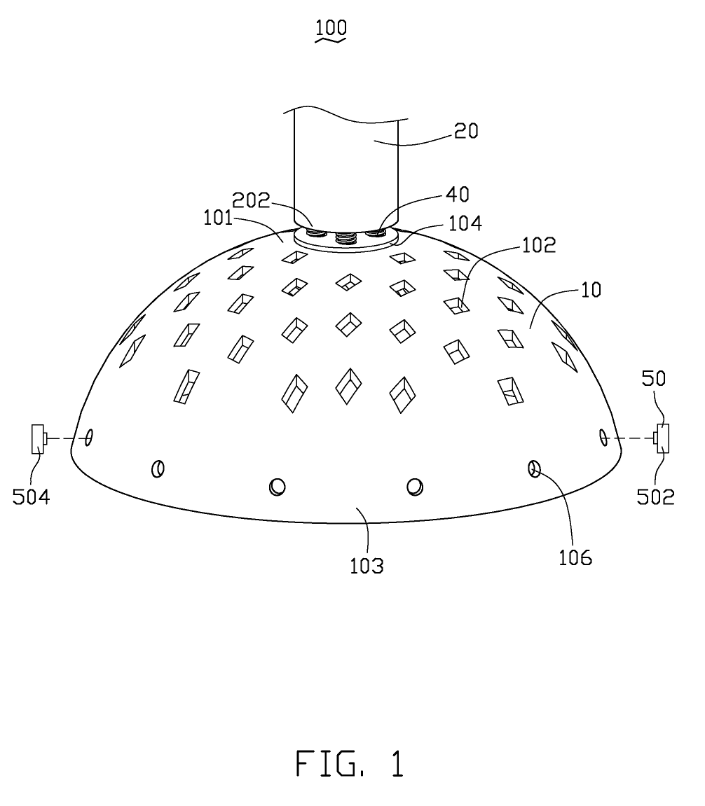

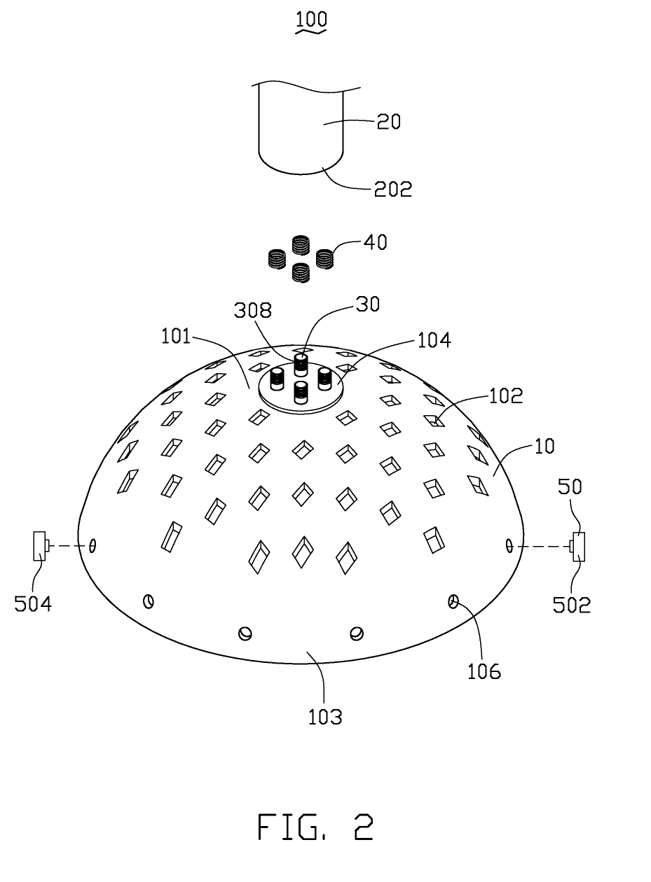

Referring to FIGS. 1 to 3, one embodiment of a vapor deposition device 100 includes a support component 10, a connecting member 20, a plurality of securing members 30, a plurality of elastic members 40, and an inspecting component 50.

The support component 10 may be semi-spherical shaped, and has a top portion 101 and a bottom portion 103. A plurality of receiving holes 102 is defined in the support component 10 between the top portion 101 and the bottom portion 103, and configured to receive workpieces. A plurality of pairs of through holes 106 is defined in the support component 10 adjacent to the bottom portion 103. Each pair of through holes 106 is substantially coaxial with each other and positioned in a horizontal plane. In one embodiment, axes of each pair of through holes 106 intersect an axis of the support member 10. A protrusion portion 104 is formed on the top portion 101. A plurality of first securing holes 108 may be evenly defined in the protrusion portion 104. The support component 10 may be made of materials having high heat conductivities, such as copper and aluminum.

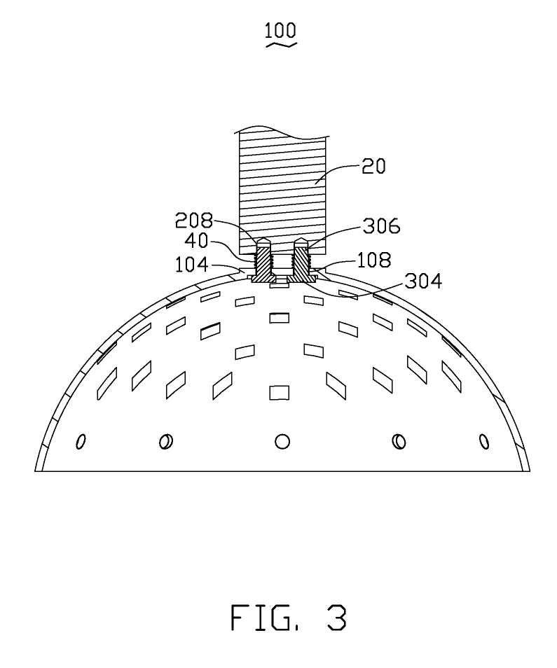

Each securing member 30 has a first end 304 and a second end 306 opposite to the first end 304 (seeing FIG. 3). The width of each first securing hole 108 is less than the width of the first end 304, and is larger than the width of the second end 306. An outer thread 308 is defined on the second end 306 of each securing member 30.

The connecting member 20 may be rod-shaped and may be configured to be driven to rotate the support member 10. The connecting member 20 has a connecting end 202. A plurality of second securing holes 208 is defined in the connecting end 202 corresponding to the first securing holes 108. An inner thread is defined in each second securing hole 208. Each elastic member 40 may be a spring or an elastic sheet.

The inspecting component 50 is configured to inspect whether the support member 10 is arranged in a horizontal position. The inspecting component 50 includes a light emitting member 502 and a light receiving member 504. In one embodiment, the light emitting member 502 may be an infrared light source.

In assembly, each securing member 30 passes through a corresponding first securing hole 108. The first end 304 of each securing member 30 contacts an inner surface of the support member 10. Each elastic member 40 surrounds a corresponding securing member 30 and is compressed between the protrusion portion 104 and the connecting end 202. The outer thread of each second end 306 engages with the inner thread of a corresponding second securing hole 208. The light emitting member 502 and the light receiving member 504 are positioned on both sides of the support member 10 and aligned with one pair of through holes 106. The light emitting member 502 is turned on to emit light. If the support member 10 is arranged in a horizontal position, the light would pass through the pair of through holes 106 and be received by the light receiving member 504. Otherwise, the light receiving member would not receive the light, and the securing members 30 can be adjusted to arrange the support member 10 in a horizontal position.

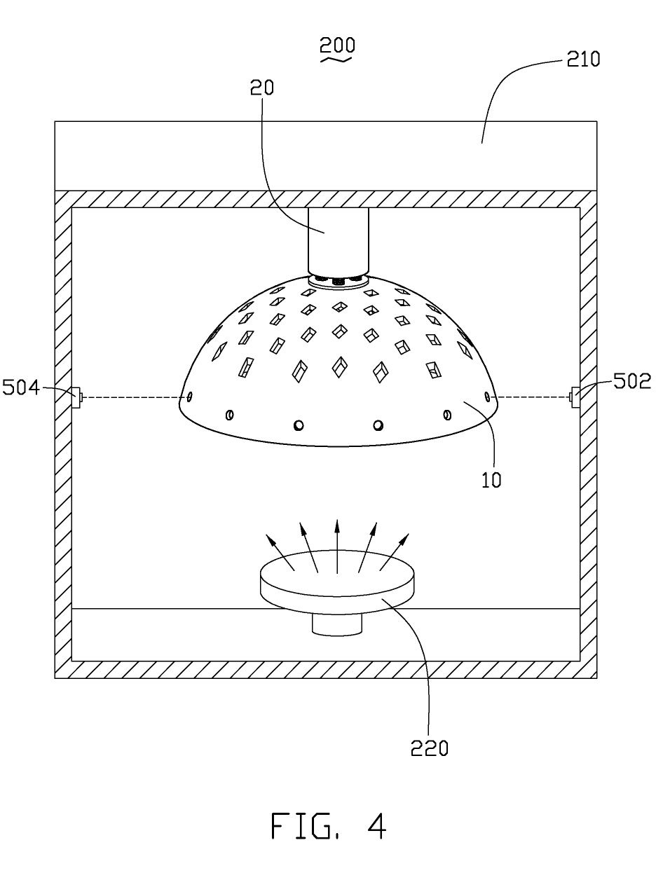

Referring to FIG. 4, another embodiment of a vapor deposition device 200 is similar to the vapor deposition device 100 of FIGS. 1 to 3, except that the vapor deposition device 200 further includes a vacuum container 210 and a crucible 220. The vacuum container 210 is configured to conduct a depositing process in a vacuum environment and prevent contaminants from entering and contaminating the workpieces. The crucible 220 is configured to support film materials. The connecting member 20, the light emitting member 502 and the light receiving member 504 are secured on an inner surface of the vacuum container 210. The support member 10 is positioned above the crucible 220.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A vapor deposition device, comprising:
a connecting member having a connecting end;
a support member having a bottom portion and a top portion positioned on the connecting end; wherein a plurality of receiving holes is defined in the support component between the top portion and the bottom portion and configured to receive workpieces; a plurality of pairs of through holes is defined in the support component adjacent to the bottom portion; each pair of through holes is substantially coaxial with each other and positioned in a horizontal plane; and
an inspecting component comprising a light emitting member and a light receiving member configured to be aligned with one of the pairs of through holes.

2. The vapor deposition device of claim 1, wherein the support member is semi-spherical shaped.

3. The vapor deposition device of claim 2, wherein axes of each pair of through holes intersect an axis of the support member.

4. The vapor deposition device of claim 1, further comprising a plurality of securing members and a plurality of elastic members, wherein the support member has a protrusion portion positioned on the top portion; a plurality of first securing holes is defined in the protrusion portion; each securing member passes through a corresponding first securing hole, and has a first end and a second end opposite to the first end; the first end is positioned on the support member; the second end is positioned on the connecting end; each elastic member surrounds a corresponding securing member and is compressed between the connecting end and the protrusion portion.

5. The vapor deposition device of claim 4, wherein the width of each first securing hole is less than the width of the first end, and is larger than the width of the second end; a plurality of second securing holes is defined in the connecting end; the first end of each securing member contacts an inner surface of the support member; the second end of each securing member is fixed in a corresponding second securing hole.

6. The vapor deposition device of claim 5, wherein an outer thread is defined on the second end of each securing member; an inner thread is defined in each second securing hole and engaged with the outer thread.

7. The vapor deposition device of claim 4, wherein each elastic member is a spring or an elastic sheet.

8. The vapor deposition device of claim 1, wherein the light emitting member is an infrared light source.

9. The vapor deposition device of claim 1, wherein the connecting member is rod-shaped.

10. The vapor deposition device of claim 1, wherein the support member is made of material selected from the group consisting of copper and aluminum.

11. The vapor deposition device of claim 1, further comprising a vacuum container and a crucible; wherein the connecting member, the light emitting member, and the light receiving member are positioned on an inner surface of the vacuum container; the support member is positioned above the crucible.

12. A support member for a vapor deposition device, comprising a bottom portion and a top portion; wherein a plurality of receiving holes is defined in the support component between the top portion and the bottom portion and configured to receive workpieces; a plurality of pairs of through holes is defined in the support component adjacent to the bottom portion; each pair of through holes is substantially coaxial with each other and positioned in a horizontal plane.

13. The support member of claim 12, wherein the support member is semi-spherical shaped.

14. The support member of claim 12, wherein axes of each pair of through holes intersect an axis of the support member.

15. The support member of claim 12, further comprising a protrusion portion positioned on the top portion; a plurality of securing holes being defined in the protrusion portion.
